(19) United States
(12) Patent Application Publication
(10) Pub. No.: US 2026/0082958 A1
(43) Pub. Date: Mar. 19, 2026

(54) SEMICONDUCTOR PACKAGE AND METHOD FOR MAKING THE SAME

(71) Applicant: STATS ChipPAC Pte. Ltd., Singapore (SG)

(72) Inventors: JongTae KIM, Incheon (KR); HangChul CHOI, Gyeonggi-do (KR); NamJu CHO, Gyeonggi-do (KR); HeeSoo Linda LEE, Incheon (KR)

(21) Appl. No.: 19/328,231

(22) Filed: Sep. 15, 2025

(30) Foreign Application Priority Data
Sep. 14, 2024 (CN) 202411289430.X

(51) Int. Cl. H01L 23/538; H01L 21/56; H01L 23/00; H01L 23/28; H01L 25/00

(52) U.S. Cl. CPC H10W 70/65; H10W 70/611; H10W 70/635; H10W 74/00; H10W 90/00; H10W 72/07236; H10W 74/01; H10W 90/724

(57) ABSTRACT

A method for making semiconductor package, wherein the method comprises: providing a substrate and a plurality of semiconductor dice; forming an integrated interposer block comprising a first interposer layer, a second interposer layer and a dummy portion, wherein the integrated interposer block defines a central axis, wherein the first interposer layer and the second interposer layer are symmetric with respect to the central axis to form an interposer pyramid; removing the dummy portion from the integrated interposer block to form a pair of step structures, wherein each step structure comprises two step surfaces; attaching the interposer pyramid on the substrate; attaching a first pair of semiconductor dice on the substrate; attaching a second pair of semiconductor dice on the first interposer layer and the first pair of semiconductor dice; and forming an encapsulant layer on the substrate to encapsulate the interposer pyramid and the semiconductor dice.

### TECHNICAL FIELD

The present application generally relates to semiconductor technology, and more particularly, to a semiconductor package and a method for making a semiconductor package.

### BACKGROUND OF THE INVENTION

Semiconductor devices are commonly found in modern electronic products, which perform a wide range of functions, such as signal processing, high-speed computation, transmitting and receiving electromagnetic signals, controlling electronic devices, and creating visual images for video displays. With the continued improvement in electronic products, it is desired to integrate more and more semiconductor dice in a single package. However, current methods for integrating semiconductor dice may have limited yield and relatively high cost.

Therefore, there is a need for an improved packaging technology for semiconductor devices with multiple semiconductor dice.

### SUMMARY OF THE INVENTION

An objective of the present application is to provide a semiconductor package having multiple semiconductor dice with enhanced efficiency in manufacture and improved applicability.

According to an aspect of the present application, a semiconductor package is provided. The semiconductor package defines a central axis, and comprises: a first unit, comprising: a substrate; an interposer stack formed on the substrate, wherein the interposer stack comprises a plurality of interposer layers that are stacked together and define a step structure on a side of the interposer stack, and wherein the step structure comprises at least two step surfaces exposed from respective interposer layers of the interposer stack; a plurality of semiconductor dice stacked together on the substrate and adjacent to the step structure of the interposer stack, wherein each semiconductor die of the plurality of semiconductor dice is attached partially on the substrate, or on one of the step surfaces of the step structure; and an encapsulant layer formed on the substrate, wherein the encapsulant layer encapsulates the interposer stack and the plurality of semiconductor dice; and a second unit, wherein the second unit has a structure substantially the same as that of the first unit, the first unit and the second unit are formed symmetrically with respect to the central axis, and wherein the first unit and the second unit are formed simultaneously.

According to another aspect of the present application, a method for making a semiconductor package is provided, comprising: providing a substrate, wherein the substrate defines a central axis; attaching a first interposer layer on the substrate symmetrically with respect to the central axis via solder bumps; attaching a first pair of semiconductor dice on the substrate symmetrically with respect to the central axis via solder bumps, wherein the first pair of semiconductor dice are adjacent to two lateral sides of the first interposer layer, respectively; attaching a second interposer layer on the first interposer layer symmetrically with respect to the central axis via solder bumps to form an interposer pyramid of the first and second interposer layers, wherein the interposer pyramid define a pair of step structures on two lateral sides of the interposer pyramid, respectively, wherein each step structure comprises two step surfaces extending from the first interposer layer and the second interposer layer on one side of the interposer pyramid; attaching a second pair of semiconductor dice on the first interposer layer and the first pair of semiconductor dice symmetrically with respect to the central axis via solder bumps; and forming an encapsulant layer on the substrate to encapsulate the interposer pyramid, the first pair of semiconductor dice, and the second pair of semiconductor dice.

According to a further aspect of the present application, a method for making a semiconductor package is provided, comprising: providing a substrate and a plurality of semiconductor dice; forming an integrated interposer block comprising a first interposer layer, a second interposer layer and a dummy portion, wherein the integrated interposer block defines a central axis, wherein the first interposer layer and the second interposer layer are symmetric with respect to the central axis to form an interposer pyramid, and the dummy portion is at a periphery of the interposer pyramid; removing the dummy portion from the integrated interposer block to form a pair of step structures on two lateral sides of the interposer pyramid, respectively, wherein each step structure comprises two step surfaces extending from the first interposer layer and the second interposer layer on one side of the interposer pyramid; attaching the interposer pyramid on the substrate; attaching a first pair of semiconductor dice on the substrate symmetrically with respect to the central axis and adjacent to two lateral sides of the first interposer layer via solder bumps, respectively; attaching a second pair of semiconductor dice on the first interposer layer and the first pair of semiconductor dice symmetrically with respect to the central axis via solder bumps; and forming an encapsulant layer on the substrate to encapsulate the interposer pyramid and the semiconductor dice.

According to another aspect of the present application, a method for making a semiconductor package is provided, comprising: providing a plurality of semiconductor dice; forming an integrated interposer block comprising a substrate, a first interposer layer, a second interposer layer and a dummy portion, wherein the integrated interposer block defines a central axis, wherein the substrate, the first interposer layer and the second interposer layer are symmetric with respect to the central axis to form an interposer pyramid, and the dummy portion is at a periphery of the interposer pyramid and on the substrate; removing the dummy portion from the integrated interposer block to expose the substrate from the dummy portion and to form a pair of step structures on two lateral sides of the interposer pyramid, respectively, wherein each step structure comprises two step surfaces extending from the first interposer layer and the second interposer layer on one side of the interposer pyramid; attaching a first pair of semiconductor dice on the substrate symmetrically with respect to the central axis and adjacent to two lateral sides of the first interposer layer via solder bumps, respectively; attaching a second pair of semiconductor dice on the first interposer layer and the first pair of semiconductor dice symmetrically with respect to the central axis via solder bumps; and forming an encapsulant layer on the substrate to encapsulate the interposer pyramid and the semiconductor dice.

It is to be understood that both the foregoing general description and the following detailed description are exemplary and explanatory only, and are not restrictive of the invention. Further, the accompanying drawings, which are incorporated in and constitute a part of this specification, illustrate embodiments of the invention and together with the description, serve to explain principles of the invention.

### BRIEF DESCRIPTION OF DRAWINGS

The drawings referenced herein form a part of the specification. Features shown in the drawing illustrate only some embodiments of the application, and not of all embodiments of the application, unless the detailed description explicitly indicates otherwise, and readers of the specification should not make implications to the contrary.

FIGS. 1A to 1C illustrate semiconductor packages according to embodiments of the present application.

FIGS. 2A to 2E illustrate semiconductor packages according to embodiments of the present application.

FIGS. 3A to 3K illustrate steps of a method for making a semiconductor package of FIG. 1A according to an embodiment of the present application.

FIGS. 4A to 4G illustrate steps of a method for making a semiconductor package of FIG. 1B according to another embodiment of the present application.

FIGS. 5A to 5H illustrate steps of a method for making a semiconductor package of FIG. 1C according to another embodiment of the present application.

FIGS. 6A to 6D illustrate different methods for attaching an upper semiconductor die of a semiconductor package of FIGS. 1A to 1C according to some embodiments of the present application.

The same reference numbers will be used throughout the drawings to refer to the same or like parts.

### DETAILED DESCRIPTION OF THE INVENTION

The following detailed description of exemplary embodiments of the application refers to the accompanying drawings that form a part of the description. The drawings illustrate specific exemplary embodiments in which the application may be practiced. The detailed description, including the drawings, describes these embodiments in sufficient detail to enable those skilled in the art to practice the application. Those skilled in the art may further utilize other embodiments of the application, and make logical, mechanical, and other changes without departing from the spirit or scope of the application. Readers of the following detailed description should, therefore, not interpret the description in a limiting sense, and only the appended claims define the scope of the embodiment of the application.

In this application, the use of the singular includes the plural unless specifically stated otherwise. In this application, the use of “or” means “and/or” unless stated otherwise. Furthermore, the use of the term “including” as well as other forms such as “includes” and “included” is not limiting. In addition, terms such as “element” or “component” encompass both elements and components including one unit, and elements and components that include more than one subunit, unless specifically stated otherwise. Additionally, the section headings used herein are for organizational purposes only, and are not to be construed as limiting the subject matter described.

As used herein, spatially relative terms, such as “beneath”, “below”, “above”, “over”, “on”, “upper”, “lower”, “left”, “right”, “vertical”, “horizontal”, “side” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The device may be otherwise oriented (rotated 90 degrees or at other orientations) and the spatially relative descriptors used herein may likewise be interpreted accordingly. It should be understood that when an element is referred to as being “connected to” or “coupled to” another element, it may be directly connected to or coupled to the other element, or intervening elements may be present.

In order to efficiently use space in a semiconductor package, multiple semiconductor dice may be stacked vertically in the package. Conventionally, electrical connections passing through a semiconductor die, such as TSV, may be formed through one or more semiconductor dice for electrically connecting the semiconductor dice at different heights. However, there are cases where such structures are not viable. The present application discloses a semiconductor package that is more universally applicable. The present semiconductor package has multiple semiconductor dice stacked together via various interposer layers. Further, the semiconductor package of the present application can provide a simplified process with a higher yield and can reduce manufacture cost.

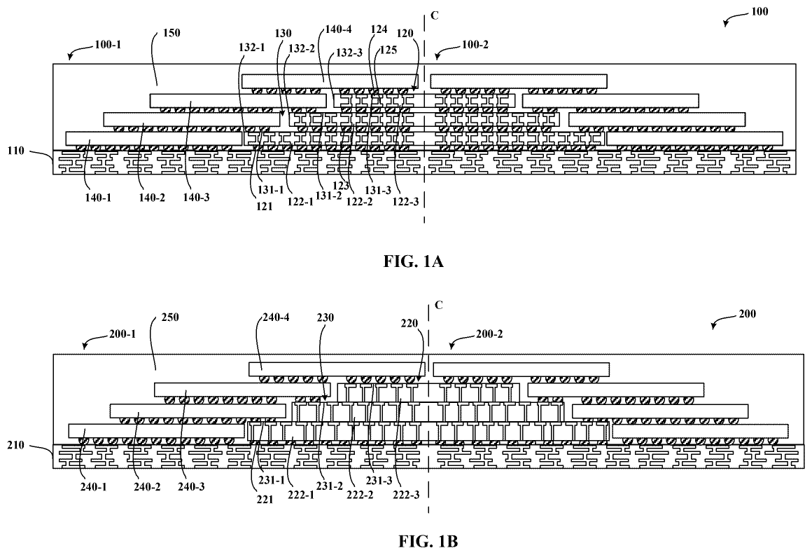

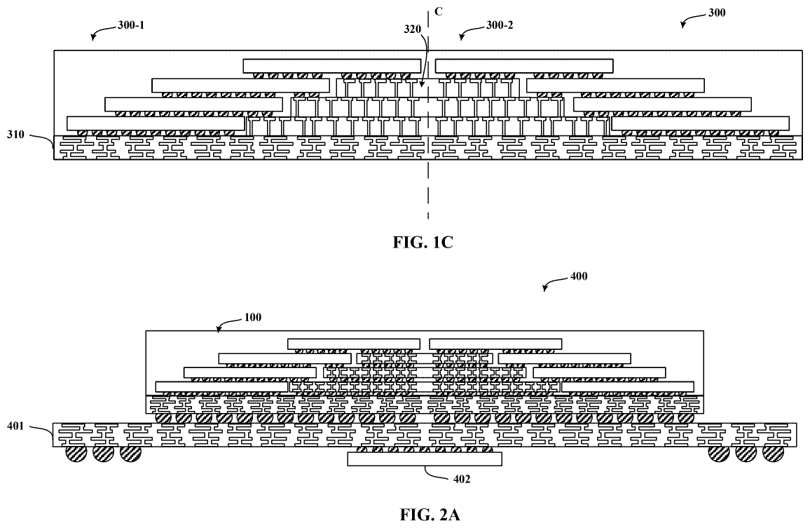

FIGS. 1A to 1C illustrate semiconductor packages 100, 200 and 300 according to embodiments of the present application. In general, all of the semiconductor packages 100, 200 and 300 include a mirrored and double-sided interposer stack.

Referring to FIG. 1A, the semiconductor package 100 includes two units 100-1 and 100-2, which have substantially the same structure, and are symmetrically formed with respect to a central axis C of the semiconductor package 100. Taking the unit 100-1 as an example, the specific structure of the two units 100-1 and 100-2 is as follows.

In particular, the unit 100-1 includes a substrate 110 which may be integrated formed with that of the unit 100-2, an interposer stack 120, a plurality of semiconductor dice 140-1, 140-2, 140-3 and 140-4 and an encapsulant layer 150 formed on the substrate 110. The interposer stack 120 provides a step structure 130 on a side of the interposer stack 120, which takes the shape of a stairstep. The step structure 130 is used for supporting the respective adjacent semiconductor dice 140-1 to 140-4 at different heights with respect to the substrate 110, while maintaining their electrical connection to the substrate 110 and preferably further between these semiconductor dice 140-1 to 140-4. The encapsulant layer 150 which is also formed on the substrate 110 encapsulates the interposer stack 120 and the semiconductor dice 140-1 to 140-4 for purpose of protection and electrical isolation.

The substrate 110 may include one or more insulating or passivation layers and one or more substrate interconnection structures formed in the insulating or passivation layers. Each substrate interconnection structure may include one or more conductive vias formed through the insulating or passivation layers, and one or more conductive layers formed on a top surface and/or a bottom surface of the substrate 110. The substrate 110 may include one or more laminated layers of polytetrafluoroethylene pre-impregnated, FR-4, FR-1, CEM-1, or CEM-3 with a combination of phenolic cotton paper, epoxy, resin, woven glass, matte glass, polyester, and other reinforcement fibers or fabrics. The substrate 110 can also be a multi-layer flexible laminate, ceramic, copper clad laminate, or glass. In some embodiments, the substrate interconnection structures or redistribution layers (RDL) inside the substrate 110 can be formed using sputtering, electrolytic plating, electroless plating, or other suitable deposition process. The conductive vias and layers may be one or more layers of Al, Cu, Sn, Ni, Au, Ag, titanium (Ti), tungsten (W), or other suitable electrically conductive material.

Still referring to FIG. 1A, the interposer stack 120 is formed on the substrate 110. Preferably, the interposer stack 120 is attached on the substrate 110 via solder bumps 121. The interposer stack 120 includes a plurality of interposer layers 122-1, 122-2 and 122-3 which are stacked together, preferably via solder bumps 123. It can also be understood that, in other embodiments, the plurality of interposer layers may be connected together using other means, such as by directly contacting the interposer layers. Each of the interposer layers 122-1, 122-2 and 122-3 may include conductive pathways, which may provide paths for power, ground, and data transmission to and from the electronic components attached thereon. In some embodiments, each interposer layer may include conductive patterns 124 on its exposed surface for electrical connection to the semiconductor die, and connection structures 125 extending and electrically passing through the interposer layer(s). In some embodiments, each conductive pathway may take the form of an e-bar as shown in FIG. 1A. That is, each e-bar may generally take the form of an embedded conductive post. It can be understood that, the structures of the conductive pathways are not limited to the embodiments shown herein. For example, the material and structure of the interposer layers may be similar to the material and structure of the substrate 110, and will not be repeated herein.

Since the interposer stack 120 has integrated therein various interposer layers, these different interposer layers may have different compositions, as well as the solder bumps therebetween, to meet different requirements of the semiconductor dice they are connecting. For example, if two semiconductor dice need to exchange a bigger current, for purpose of power supply, wider connection structures may be used for the interposer layer connecting the two semiconductor dice. For another example, if heavy data communication is desired between two semiconductor dice, denser connection structures may be used for the interposer layer connecting the two semiconductor dice, to provide more signal paths. Therefore, in some embodiments, the connection structures of the interposer layers in the interposer stack are not desired to be aligned with each other vertically.

As shown in FIG. 1A, the plurality of interposer layers 122-1 to 122-3 may together define a step structure 130 on a side of the interposer stack 120. In general, the step structure 130 has a cross-section of steps of a staircase. The step structure 130 may include at least two step surfaces. For example, as shown in FIG. 1A, the step structure 130 may have three step surfaces 131-1, 131-2 and 131-3 exposed from the interposer layers 122-1, 122-2 and 122-3, respectively. The step surfaces 131-1, 131-2 and 131-3 may include conductive patterns which are exposed for electrical connection to the semiconductor dice thereon, respectively, as desired.

Each interposer layer of the interposer stack 120 also includes a rise surface between its step surface and a lower (step) surface. Preferably, each interposer layer is formed as a cube or cuboid, and its rise surface is perpendicular to its step surface. For example, the interposer layer 122-1 includes a rise surface 132-1 perpendicular to the step surface 131-1, the interposer layer 122-2 includes a rise surface 132-2 perpendicular to the step surface 131-2, and the interposer layer 122-3 includes a rise surface 132-3 perpendicular to the step surface 131-3. It can be understood that, in other embodiments, a rise surface may take other shapes and forms, such as a slope. As illustrated below, the height of the interposer layer may be preferably the same as that of the semiconductor die at the same level as the interposer layer, so as to standardize the manufacturing process. Preferably, the interposer layers of an interposer stack may have the same height, and may be manufactured using the same process.

Still referring to FIG. 1A, the plurality of semiconductor dice 140-1 to 140-4 are also stacked together on the substrate 110 and adjacent to the step structure 130. Preferably, the semiconductor die 140-1 is at least partially attached on the substrate 110 via solder bumps, but preferably be fully attached on the substrate 110. The semiconductor die 140-2 is attached partially on the semiconductor die 140-1, and partially on the step surface 131-1 of the interposer layer 122-1. Similarly, the semiconductor die 140-3 is partially attached on the step surface 131-2 of the interposer layer 122-2, and the semiconductor die 140-4 is partially attached on the step surface 131-3 of the interposer layer 122-3. Preferably, an upper semiconductor die is attached on a lower semiconductor die via solder bumps as shown in FIG. 1A. Depending on whether conductive patterns are formed on the two surfaces of the semiconductor dice and/or the interposer layers, electrical connection or paths may or may not be formed between the two components that are physically connected through the solder bumps. For example, in some embodiments, for the semiconductor die 140-2, there is no conductive pattern formed on a portion of its bottom surface which is aligned with the top surface of the semiconductor die 140-1, and thus the solder bumps there may not electrically connect the semiconductor die 140-2 with the semiconductor die 140-1. However, there may be conductive patterns formed on the other portion of the bottom surface of the semiconductor die 140-2, which is aligned with the top surface of the interposer layer 122-1, and thus the solder bumps there may electrically connect the semiconductor die 140-2 with the interposer layer 122-1.

As described above, in the unit 100-1, the semiconductor dice 140-1 to 140-4 may achieve electrical connection with each other and to the substrate 110 via the interposer stack 120. As such, the plurality of semiconductor dice 140-1 to 140-4 do not necessarily require wire bonds or TSVs therebetween. Therefore, the manufacturing process of the unit 100-1 can be simplified and relatively stable.

In order to realize a more stable structure, heights of the interposer layer and the semiconductor die of the unit 100-1 at the same level may be similar or the same as each other. For example, the heights of the interposer layer 122-1 and the semiconductor die 140-1 may be similar, and the heights of the interposer layer 122-2 and the semiconductor die 140-2 may be similar, etc. It can be understood that solder bumps used for attaching the interposer layers and the semiconductor dice may also have the same or similar height and/or similar material. In this case, the manufacturing process can be standardized and simplified. Also, during a bonding process such as a reflow process, the solder bumps of the interposer stack and the plurality of semiconductor dice may undergo a similar change, and height difference between the interposer layer and the semiconductor die at the same level after the bonding process may be minimized, and even avoided.

Still referring to FIG. 1A, the unit 100-1 also includes the encapsulant layer 150 formed on the substrate 110 and thus on the interposer stack 120 and the semiconductor dice. In some embodiments, the encapsulant layer 150 can be a polymer composite material, such as epoxy resin, epoxy acrylate, or any suitable polymer with or without filler. The encapsulant layer 150 may be non-conductive, provide structural support, and environmentally protect the electronic devices from external environment and contaminants. The encapsulant layer 150 may be formed with any shape as desired. The encapsulant layer 150 may be formed by depositing an encapsulant or molding compound on the substrate 110 using injection molding, compressive molding, transfer molding, liquid encapsulant molding, vacuum lamination, spin coating, or another suitable processes.

As mentioned above, the unit 100-2 has substantially the same structure as the unit 100-1, and they are symmetric with respect to a central axis C of the semiconductor package 100. As shown in FIG. 1A, in some embodiments, the interposer layers of the units 100-1 and 100-2 at respective same levels may be integrated together, e.g., formed using a single piece of plate or substrate, and the stacked interposer layers may take the form of a pyramid whose size or area increases from the top layer to the bottom layer. Similarly, the substrates of the units 100-1 and 100-2 may also be integrated together. Due to the symmetry of the semiconductor package 100, the units 100-1 and 100-2 can be formed simultaneously, therefore, the manufacture efficiency and yield can be improved.

The semiconductor package of the present application such as the semiconductor 100 shown in FIG. 1A may have other variations, which will be illustrated with reference to FIG. 1B and FIG. 1C. Specifically, as shown in FIG. 1B, multiple interposer layers of the interposer stack may be integrally formed, or further, as shown in FIG. 1C, the substrates may be integrally formed with the interposer layers.

Referring to FIG. 1B, a semiconductor package 200 includes two units 200-1 and 200-2 which are symmetric with respect to a central axis C of the semiconductor package 200. Taking the unit 200-1 as an example, the unit 200-1 includes a substrate 210, an interposer stack 220 formed on the substrate 210, and a plurality of semiconductor dice 240-1 to 240-4 stacked together on the substrate 210 and adjacent to the interposer stack 220. Similar as the above embodiments, the interposer stack 220 is mounted on the substrate 210 via solder bumps 221, and includes a plurality of interposer layers 222-1, 222-2 and 222-3. These interposer layers 222-1, 222-2 and 222-3 together define a step structure 230 on a side of the interposer stack 220. The interposer layers 222-1, 222-2 and 222-3 include step surfaces 231-1, 231-2 and 231-3 which are exposed from respective interposer layers for mounting with the respective semiconductor dice.

Still referring to FIG. 1B, the plurality of semiconductor dice 240-1 to 240-4 are attached on the substrate 210 preferably via solder bumps. Each semiconductor die may be attached partially on the substrate 210, or on one of the step surfaces 231-1, 231-2 and 231-3 of the step structure 230. An encapsulant layer 250 is also formed on the substrate 210, which encapsulates the interposer stack 220 and the plurality of semiconductor dice 240-1 to 240-4.

The semiconductor package 200 is different from the above semiconductor package 100 shown in FIG. 1A in that, in each unit of the semiconductor package 200, the interposer stack is integrally formed together prior to being attached on the corresponding substrate. That is, instead of being attached with each other via additional solder bumps before or when they are attached individually on the substrate, interposer layers of the interposer stack 220 may be formed integrally as a single piece, and conductive pathways are formed inside and through the multiple interposer layers. For illustration purpose, interfaces between the layers are shown in FIG. 1B to distinguish different interposer layers. Other configurations of the semiconductor package 200 may refer to the semiconductor package 100, and shall not be repeated herein.

As shown in FIG. 1C, the semiconductor package 300 is generally similar as the semiconductor package 200 shown in FIG. 1B. Different from the semiconductor package 200, in a unit 300-1 of the semiconductor package 300, the interposer stack 320 and the substrate 310 are further integrally formed together as a single piece. Similarly, in a unit 300-2 which is symmetric to the unit 300-1, the interposer stack and the substrate are also integrally formed together as a single piece. Further, in some embodiments, the interposer stacks and the substrates of the two units are all integrally formed together.

As illustrated above, each of the semiconductor packages 100, 200 and 300 as illustrated in FIGS. 1A to 1C includes a mirrored, double sided interposer stack structure. Such mirrored structure allows for efficient manufacture and higher UPH (unit per hour).

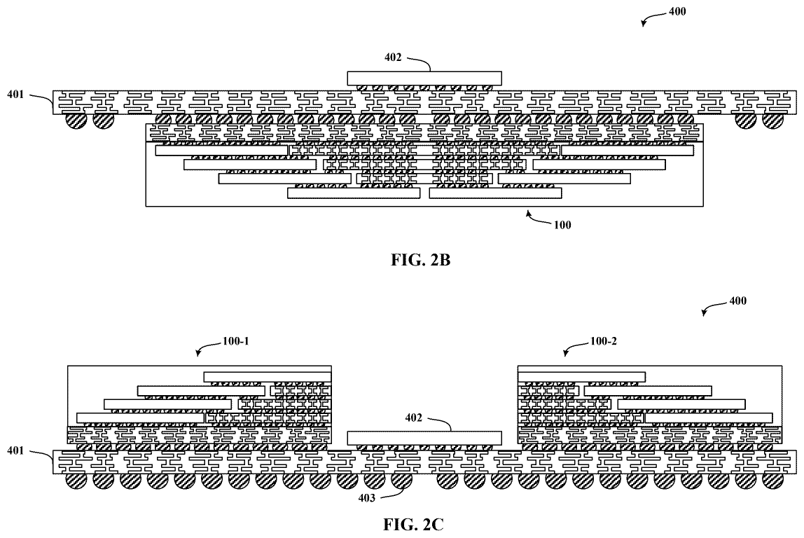

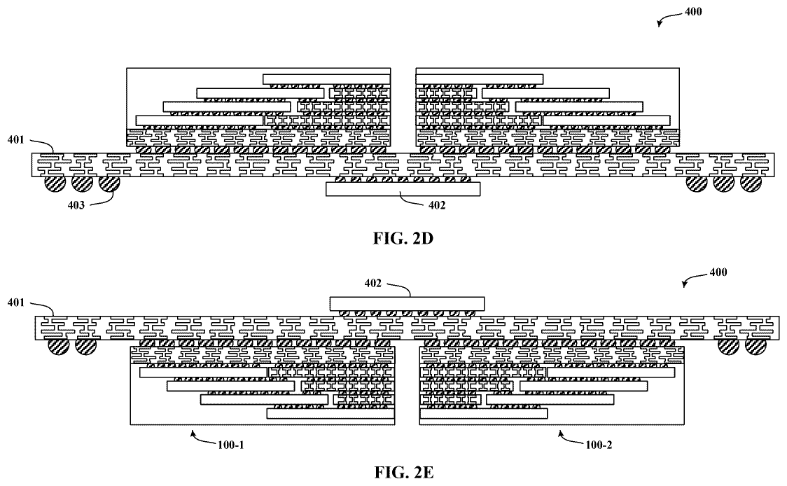

Variations can be made to the semiconductor packages illustrated above, for example, other electronic components can be integrated together to form a larger semiconductor package. FIGS. 2A to 2E illustrate semiconductor packages according to further embodiments of the present application.

In some embodiments, the semiconductor package as illustrated in FIGS. 1A to 1C may be directly integrated with other electronic components. Referring to FIG. 2A, the semiconductor package 100 may be attached to a front surface of a base substrate 401, a base semiconductor die 402 may be attached to a back surface of the base substrate 401, and solder bumps may be arranged at a periphery of the back surface 401 for external electrical connection. Referring to FIG. 2B, in some embodiments, the semiconductor package 100 may be attached to the back surface of the base substrate 401, and the base semiconductor die 402 may be attached to the front surface of the base substrate 401. Herein, the base substrate 401 facilitates the electrical connection between the units 100-1 and 100-2 and the base semiconductor die 402.

In some embodiments, the semiconductor packages as illustrated in FIGS. 1A to 1C may be first singulated at the central line C to obtain separated units 100-1 and 100-2, and the separated units can then be integrated with other electronic components. Referring to FIG. 2C, the semiconductor package 400 includes a base substrate 401 and units 100-1 and 100-2 singulated from each other from the semiconductor package 100. The units 100-1 and 100-2 are mounted on a front surface of the base substrate 401 and spaced from each other. In some embodiments, a base semiconductor die 402 is also mounted on the front surface of the base substrate 401 and between the units 100-1 and 100-2. Herein, the base substrate 401 facilitates the electrical connection between the units 100-1 and 100-2 and the base semiconductor die 402. Further, a back surface of the base substrate 401 may be mounted with solder bumps 403 for electrically connecting the semiconductor package 400 with other external devices.

Referring to FIG. 2D, compared to FIG. 2C, in some other embodiments, the base semiconductor die 402 can be mounted to a back surface of the base substrate 401 without occupying a region of the front surface of the base substrate 401. Accordingly, solder bumps 403 may be arranged at a periphery of the back surface of the base substrate 401, distant from the base semiconductor die 402 at the central region. In this way, the semiconductor package 400 so form can maintain the substantially mirrored structure.

Referring to FIG. 2E, in some embodiments, the base semiconductor die 402 may be attached onto the front surface of the base substrate 401, while the units 100-1 and 100-2 may be attached onto the back surface. In other words, the units 100-1 and 100-2 may be on the same side of the base substrate 401 as solder bumps 403.

In the semiconductor package 400 illustrated above, preferably, the base semiconductor die 402 is a system-on-chip. In some embodiments, the base semiconductor die 402 can be a device that generates more heat than the semiconductor dice inside units 100-1 and 100-2. Such configuration is advantageous since the whole semiconductor package 400 can have a compact structure design, while the base semiconductor die 402 remains exposed, and heat dissipation of the base semiconductor die 402 can be improved.

It can be understood that, FIGS. 2A to 2E exemplarily show that the units singulated from the semiconductor package 100 can be integrated into a larger semiconductor package, such integration can also be applied to the units of semiconductor packages 200 and 300 shown in FIGS. 1B and 1C.

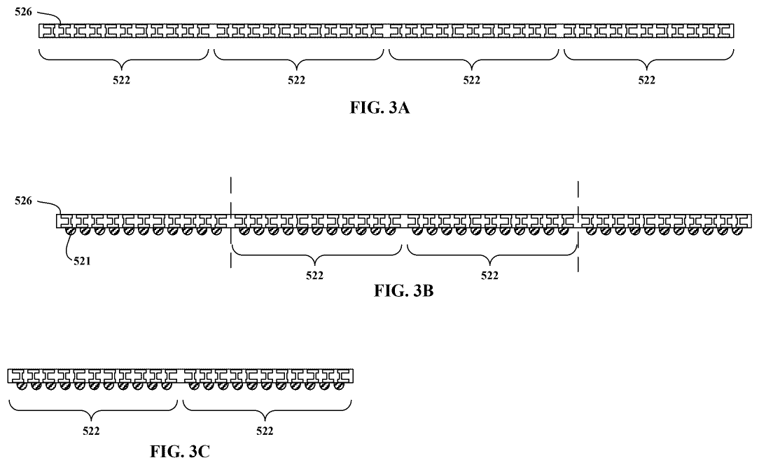

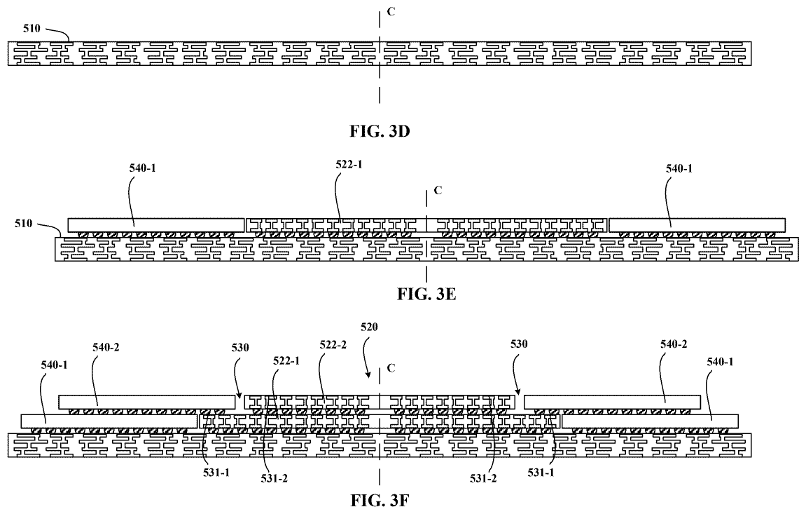

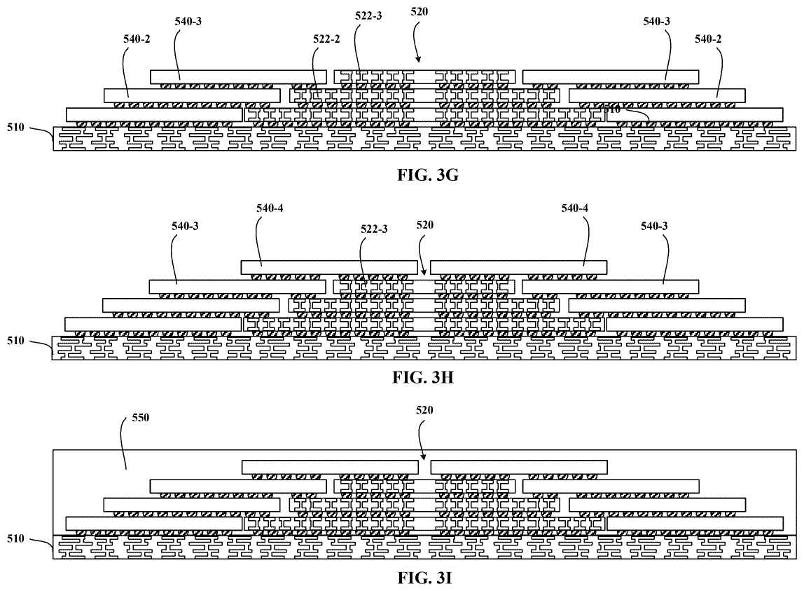

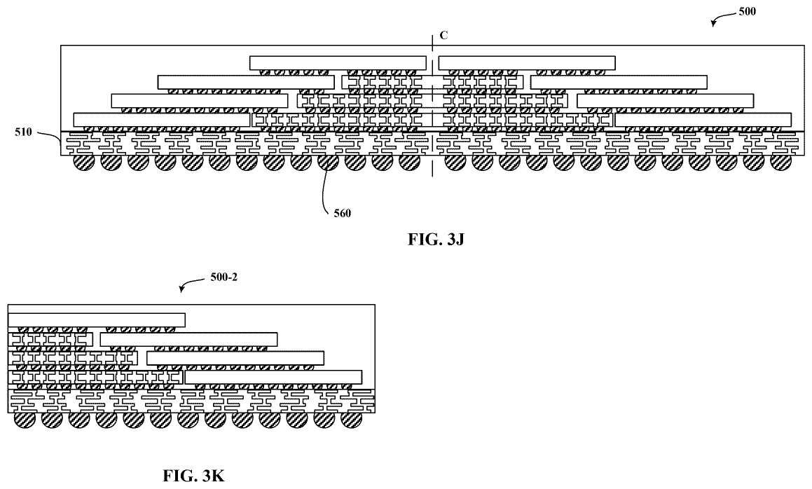

FIGS. 3A to 3K illustrate steps of a method for making a semiconductor package according to an embodiment of the present application. For example, the method may be used to form the semiconductor package shown in FIG. 1A.

Referring to FIGS. 3A to 3C, in some embodiments, interposer layers can be first prepared before being attached on the substrate. In some embodiments, each interposer layer can take the form of an e-bar stripe.

Referring to FIG. 3A, a base stripe 526 containing e-bars can be formed. The base stripe 526 may include plurality sets 522 of e-bar. Each set may include multiple e-bars. Each e-bar may generally take the form of an embedded conductive post. In some embodiments, each conductive post may also be accompanied with conductive patterns on the upper and lower surfaces of the post for providing larger electrical contact. Distance may be remained between adjacent sets of e-bars for optional singulation afterwards. Preferably, each set of e-bars may have a same length, and can function as an interposer layer in a unit of the semiconductor packages 100 to 300 illustrated above, and adjacent sets of e-bars can be used as symmetrically integrated interposer layers in further steps.

Referring to FIG. 3B, in some embodiments, the base stripe 526 is pre-formed with solder bumps 521 before being attached to another base. It can be understood that, in other embodiments, the base stripe 526 may not be pre-formed with solder bumps.

Referring to FIG. 3C, a sub-stripe including two sets of e-bars is singulated from the bigger base stripe. Therefore, the sub-stripe with two sets of e-bars 522 can serve as two symmetrically integrated interposer layers. As can be understood, the two symmetrically integrated interposer layers may also be deemed as a single interposer layer.

As mentioned above, interposer layers of a semiconductor package may take any desired form. In some embodiments, an interposer layers may take the form generally same as a substrate with or without pre-formed solder bumps.

Referring to FIG. 3D, a substrate 510 is provided as a package base for accommodating electronic components thereon. Specifically, the substrate 510 defines a central axis C for further formation of symmetric semiconductor packages.

Referring to FIG. 3E, an interposer layer 522-1 and a pair of semiconductor dice 540-1 are attached on the substrate 510 via solder bumps. Specifically, the interposer layer 522-1 can be obtained from the steps as shown in FIGS. 3A to 3C. The interposer layer 522-1 is formed to be symmetric with respect to the central axis C. The pair of semiconductor dice 540-1 are attached adjacent to two lateral sides of the interposer layer 522-1, respectively. Similarly, the pair of semiconductor dice 540-1 are disposed to be symmetric with respect to the central axis C.

Preferably, the interposer layer 522-1 and the semiconductor dice 540-1 may be of the same height, and the solder bumps underneath the interposer layer 522-1 and the solder bumps underneath the semiconductor dice 540-1 may be of the same height and of the same material. Therefore, during a reflow process, the bumps of the interposer layer 522-1 and the semiconductor dice 540-1 may undergo the same or similar change in height. Preferably, after an interposer layer and a semiconductor dice at the same level are disposed on a lower base or layer, a bonding process can be performed to bond the interposer layer and the semiconductor die with the lower base or layer. In this way, the interposer layer and the semiconductor die supported on the lower base or layer has a better stability and thus can serve as a base for further attachment of additional layers of components and structures thereon.

Referring to FIG. 3F, an upper interposer layer 522-2 is attached on the relatively lower interposer layer 522-1 via solder bumps, and specifically, the upper interposer layer 522-2 is also attached symmetrically with respect to the central axis C. Therefore, the two interposer layers 522-1 and 522-2 together form an interposer pyramid 520. Specifically, the interposer pyramid 520 defines a pair of step structure 530 on two lateral sides of the interposer pyramid 520, respectively. Herein, each step structure 530 includes two step surfaces 531-1 and 531-2 extending from the lower interposer layer 522-1 and the upper interposer layer 522-2 on a side of the interposer pyramid 520.

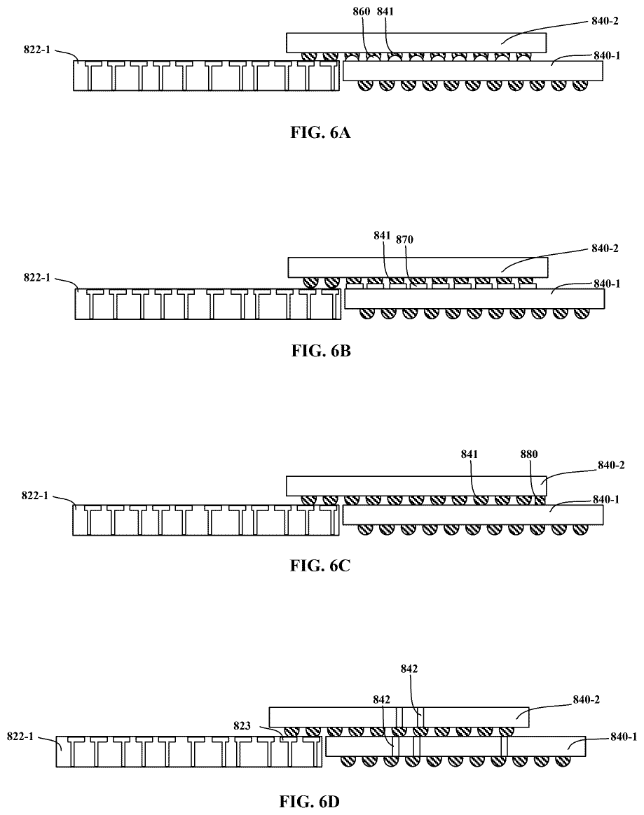

Still referring to FIG. 3F, a pair of upper semiconductor dice 540-2 are attached on both the relatively lower semiconductor dice 540-1 and the relatively lower interposer layer 522-1, preferably via solder bumps. The upper semiconductor dice 540-2 are attached symmetrically with respect to the central axis C. Similar as that illustrated in FIG. 3E, preferably, the height of the interposer layer 522-2 is similar or the same as the semiconductor dice 540-2. In some other embodiments, the attachment of an upper semiconductor die on a lower semiconductor die may include other techniques such as that illustrated with FIGS. 6A to 6D.

Referring to FIG. 3G, similar to FIG. 3F, another upper interposer layer 522-3 is attached on the relatively lower interposer layer 522-2 via solder bumps, and another pair of upper semiconductor dice 540-3 is attached both on the relatively lower semiconductor dice 540-2 and the relatively lower interposer layer 522-2, preferably via solder bumps. As shown in FIG. 3G, the interposer layer 522-3 may constitute a part of the interposer pyramid 520. Preferably, in the interposer pyramid 520, the interposer layers have a decreasing length or width from bottom to top. In this way, the top surfaces of the interposer layers may be at least partially exposed, and thus can be used for attachment of components thereon.

Still referring to FIG. 3G, the interposer pyramid 520 includes three interposer layers, and the interposer layer 522-3 which is farthest from the substrate 510 defines a top interposer layer.

Referring to FIG. 3H, Another pair of semiconductor dice 540-4 are attached both on the top interposer layer 522-3 and the semiconductor dice 540-3. It can be understood that, in some embodiments, other electronic components may be attached on the interposer layer 522-3 and the semiconductor die 540-3. For example, a further layer of interposer layer and semiconductor die may be attached.

Referring to FIG. 3I, an encapsulant layer 550 is formed on the substrate 510 to encapsulate the interposer pyramid 520 and the semiconductor dice. The encapsulant layer 550 may be formed by depositing an encapsulant or molding compound on the substrate 510 using injection molding, compressive molding, transfer molding, liquid encapsulant molding, vacuum lamination, spin coating, or another suitable processes.

Referring to FIG. 3J, solder bumps 560 may be mounted on a bottom surface of the substrate 510 to form a semiconductor package 500. Therefore, the electronic components on the substrate 510 may achieve electrical connection with external devices through the solder bumps 560.

Referring to FIG. 3K, in some embodiments, the method further includes a step of singulating at the central axis C of the semiconductor package 500, thereby, half of the semiconductor package 500-2 can be obtained. It can be understood that, the half 500-2 itself may constitute a semiconductor package. It can be understood that, the aforementioned method for forming the semiconductor package 600 or the semiconductor package 500-2 facilitates an efficient manufacture process with a mirrored, double-sided interposer stack. Due to the symmetry of the overall structure, two symmetric semiconductor packages may be manufactured simultaneously, which would improve yield and UPH.

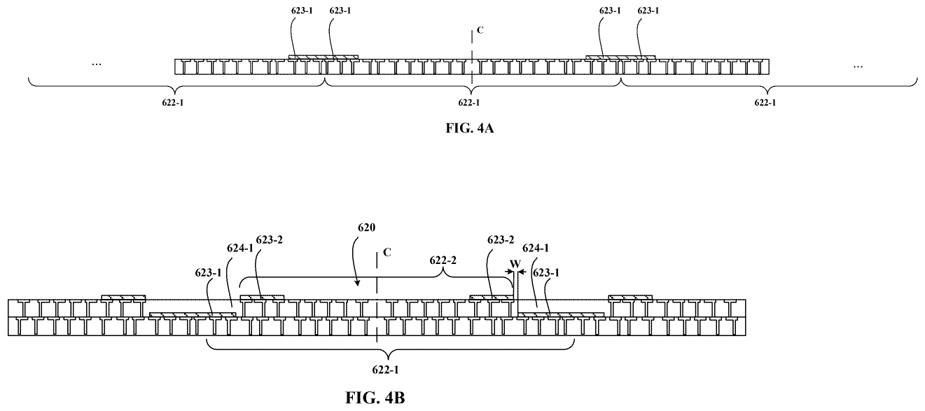

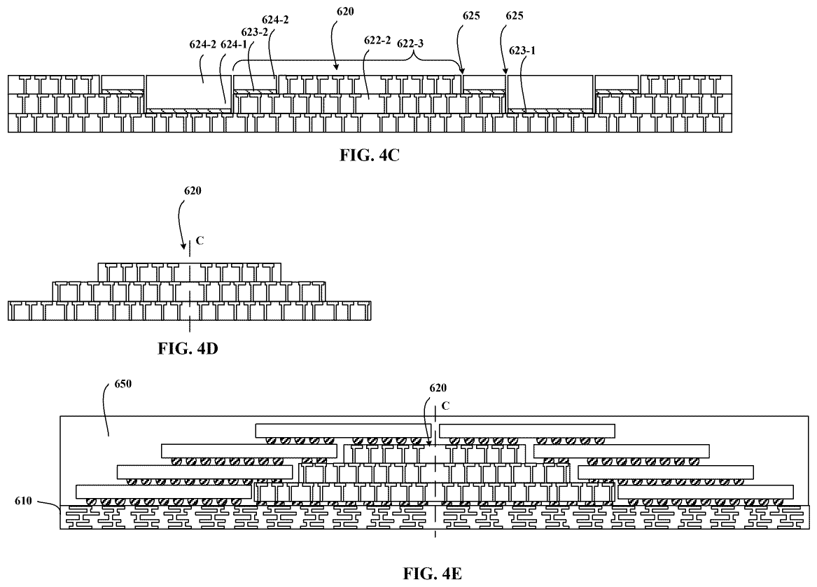

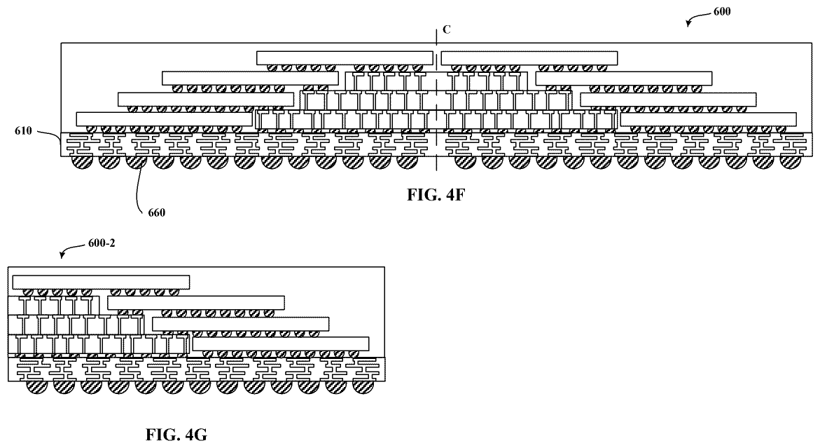

FIGS. 4A to 4G illustrate steps of a method for making a semiconductor package according to another embodiment of the present application. For example, the method may be used to form the semiconductor package shown in FIG. 1B.

Different from the method for making the semiconductor package 500 as shown in FIGS. 3A to 3K, an interposer pyramid may be formed by the steps illustrated below. Then, the interposer pyramid and semiconductor dice are attached on a substrate, and an encapsulant layer is formed on the substrate. Steps similar as the method for making the semiconductor package 500 as shown in FIGS. 3A to 3K may refer to the above embodiments.

The formation of the interposer pyramid is shown in FIGS. 4A to 4D. Referring to FIG. 4A, a first interposer layer 622-1 with a layer of connection structures is formed. The connection structures may include a set of die connection structures for further electrically coupling corresponding semiconductor dice on the step surfaces, and a set of interlayer connection structures extending through the layer of connection structures. After the first interposer layer 622-1 is formed, a barrier layer 623-1 is formed on the first interposer layer 622-1. The barrier layer 623-1 helps define a position where a step surface of the step structure of the interposer pyramid is formed. Preferably, for a bottom first interposer layer 622-1, the barrier layer 623-1 is formed on two lateral sides of the interposer layer 622-1, so that the interposer pyramid is at the center of the entire structure. The formation of the barrier layer 623-1 is symmetric with respect to a center axis C of the first interposer layer 622-1. As shown in FIG. 4A, multiple first interposer layers 622-1 can be formed simultaneously and continuously on a wafer level, and accordingly, multiple barrier layers 623-1 for the multiple first interposer layers 622-1 can also be formed simultaneously and continuously. It can be seen that the present method allows for the simultaneous formation of multiple semiconductor packages, which is advantageous for efficient manufacture.

Specifically, the barrier layer 623-1 may have a similar material and composition as a dummy layer. In some embodiments, the barrier layer 623-1 may include a release material, which may be any suitable material that allows separating the barrier layer 623-1 from the materials at both sides of the barrier layer 623-1 when sufficient force is applied. For example, the barrier layer 623-1 may be siloxanes (silicone-based polymers), or flaky materials (e.g., talc). The barrier layer 623-1 may be formed using any suitable technique such as screen printing. In some embodiments, the barrier layer 623-1 may be a metal layer, for example, a copper layer that serves as a laser drilling stop layer, it may absorb the thermal energy produced by the laser light.

Referring to FIG. 4B, a second interposer layer 622-2 with a layer of connection structures inside is further formed on the first interposer layer 622-1. Specifically, the connection structures of the second interposer layer 622-2 are formed at a location on the first interposer layer 622-1 except above the barrier layer 623-1, and a dummy portion 624-1 is formed on the barrier layer 623-1. In general, all of the first interposer layer 622-1, the second interposer layer 622-2 and the dummy portion 624-1 are symmetric with respect to the central axis C. The first interposer layer 622-1 and the second interposer layer 622-2 together form an interposer pyramid 620, and the dummy portion 624-1 is at a periphery of the interposer pyramid 620, and the first interposer layer 622-1, the second interposer layer 622-2 and the dummy portion 624-1 together form an integrated interposer block.

In some embodiments, further interposer layers can be formed. Accordingly, further barrier layers need to be formed. Still referring to FIG. 4B, similar as the process shown in FIG. 4A, in order to form the step structure with a further interposer layer, a barrier layer 623-2 is further formed on the second interposer layer 622-2 at a location for the step surface of the step structure. The barrier layer 422-2 is formed symmetrically with respect to a center line C and at two lateral sides of the interposer pyramid 620. Specifically, in the horizontal direction, the barrier layer 623-2 is formed inside of the barrier layer 623-1. There remains a gap W between adjacent edges of the barrier layer 623-2 and the barrier layer 623-1. As will be illustrated below, the gap W is used for further forming openings and detaching dummy portions. At the bottom of the openings, a conner of a step surface will be formed. Along an inner surface of the openings, a rise surface perpendicular to a step surface will also be formed. It can be understood that, since openings are formed for the corner of a step surface, the barrier layers 623-1, 623-2 do not need to extend to the openings, i.e., conners of the lower step surfaces. As such, step surfaces except the top step surface may be formed with the respective barrier layers.

Referring to FIG. 4C, similar as the process shown in FIG. 4B, a third interposer layer 622-3 is further formed on the second interposer layer 622-2 to form a higher interposer pyramid 620, and a dummy portion 624-2 is further formed on the dummy portion 624-1 and on the barrier layer 623-2. No electronic connection is formed at a position on a barrier layer, and the dummy portions 624-1 and 624-2 may together define an overall dummy portion at a periphery of the interposer pyramid 620.

Further, a drilling process, such as laser drilling, is performed to form openings 625 at the locations of conners of the lower step surfaces, so as to expose the conners of the lower step surfaces. By forming the openings 625, rise surfaces of the step structure of the interposer stack may be formed. Also, the dummy portions 624-1 and 624-2 can be easily removed since the side surfaces of the dummy portions are not in contact with the interposer pyramid 620.

Referring to FIG. 4D, along the openings 625 and the barrier layers 623-1 and 623-2, the dummy portions are removed. As illustrated above, the barrier layers 623-1 and 623-2 may use a release material that has chemical and physical properties that allow the dummy portion to be removed from the barrier layers 623-1, 623-2 by exerting a mechanical force, without deforming the interposer pyramid 620. The removal of the dummy portion from the integrated interposer block may be performed using any suitable techniques. For example, the dummy portion and the interposer pyramid 620 may be removed from each other using a vacuum device. The barrier layers 623-1 and 623-2 can also be removed using any suitable processes. Upon removing the barrier layers 623-1, 623-2 and the dummy portion, the interposer pyramid 620 which is symmetric with respect to the central axis C is remained. Specifically, a pair of step structures on two lateral sides of the interposer pyramid may be formed, and the step surfaces extending from the interposer layers on each side of the interposer pyramid are exposed. Also, as shown in FIG. 4D, the interposer pyramid 620 can be singulated from other adjacent interposer pyramids together formed on a wafer level.

Referring to FIG. 4E, the interposer pyramid 620 is attached on the substrate 610 via solder bumps. After the interposer stack 620 is attached, a plurality of semiconductor dice can be sequentially stacked adjacent to the interposer pyramid 620 and symmetrically with respect to the central axis C. The attachment of the plurality of semiconductor dice may refer to the above embodiments and will not be repeated herein. Then, an encapsulant layer 650 can be formed on the substrate 610 to encapsulate the components thereon to obtain the semiconductor package 600.

Referring to FIG. 4F, in some embodiments, solder bumps 660 may be mounted on a bottom surface of the substrate 610 to form a semiconductor package 600.

Referring to FIG. 4G, in some embodiments, the method further includes a step of singulating at the central axis C of the semiconductor package 600, and therefore, half of the semiconductor package 600-2 can be obtained. It can be understood that the half 600-2 itself may define a semiconductor package.

It can be understood that, in the semiconductor package 600, since the interposer stack 620 is integrally formed as a single piece, the plurality of semiconductor dice can also be attached together at one time, and an upper semiconductor die does not have to be attached after the bonding process for a lower semiconductor die. This helps to further simplify the manufacturing process and enhance efficiency.

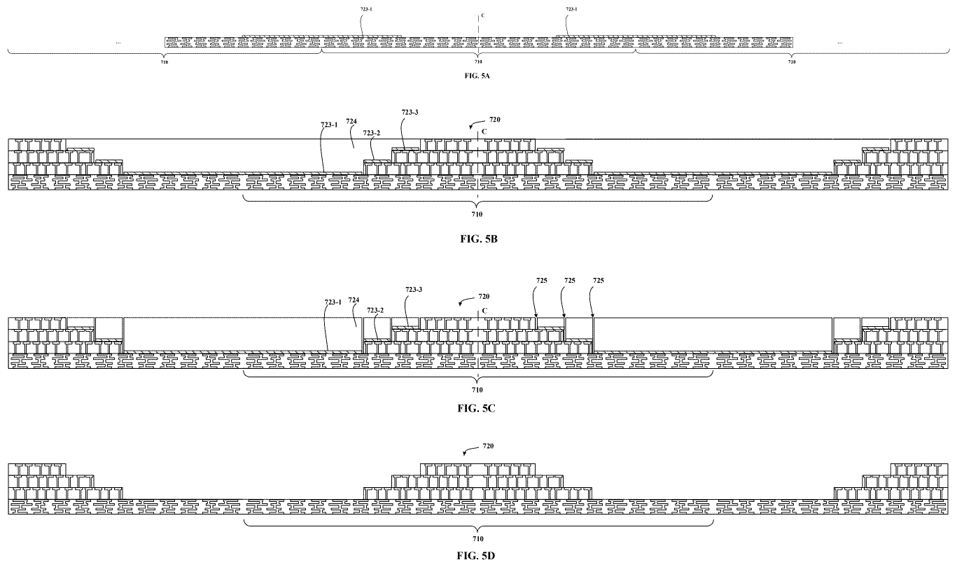

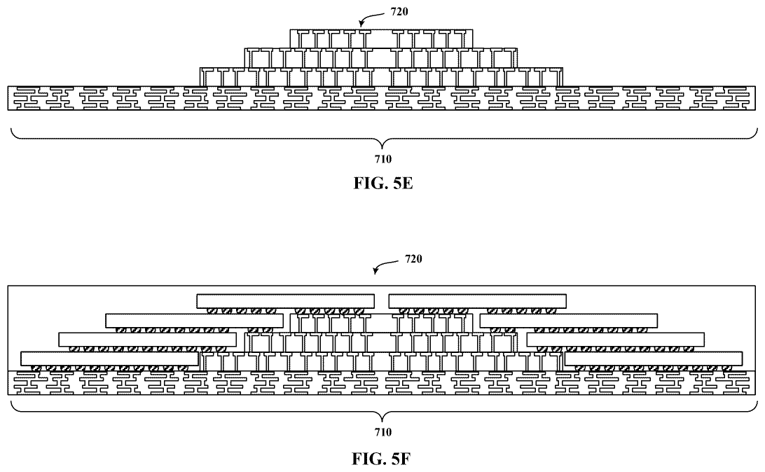

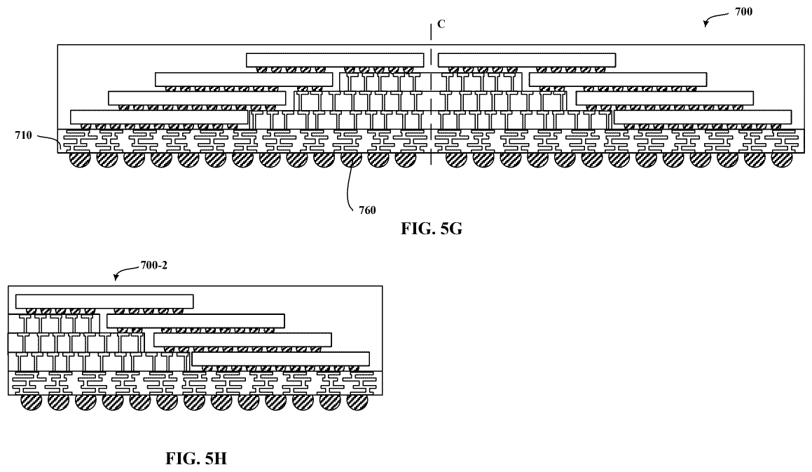

FIGS. 5A to 5H illustrate steps of a method for making a semiconductor package according to another embodiment of the present application. For example, the method may be used to form the semiconductor package shown in FIG. 1C.

Referring to FIG. 5A, a substrate 710 is provided. A barrier layer 723-1 is formed on the substrate 710. Preferably, the barrier layer 723-1 is on two lateral sides of the substrate 710. Specifically, the barrier layer 723-1 is formed at a position where the substrate 710 should be exposed for further attachment of semiconductor dice. The substrate 710 and the barrier layer 723-1 generally define a position of the central axis C, which also serves as a central axis of the interposer pyramid to be formed. In some embodiments, multiple substrates 710 can be provided simultaneously and continuously formed at a wafer level, and in this case, each semiconductor package can be singulated afterwards.

Referring to FIG. 5B, similar as the process shown in FIGS. 4B and 4C, multiple interposer layers and barrier layers are symmetrically formed on the substrate 710 with respect to the central axis C. Specifically, the interposer layers together form an interposer pyramid 720. The barrier layers 723-2 and 723-3 are formed at locations of the step surfaces, and a dummy portion 724 is formed on the barrier layers 723-1, 723-2 and 723-3 and at a periphery of the interposer pyramid 720. Herein, the substrate 710, the interposer pyramid 720, and the dummy portion 724 together constitute an integrated interposer block.

Referring to FIG. 5C, openings 725 are formed at edges of the barrier layers 723-1, 723-2 and 723-3 for removal of the dummy portion 724. Then the interposer pyramid 720 integrated with the substrate 710 underneath can be obtained as shown in FIG. 5D.

Referring to FIG. 5E, in some embodiments, multiple substrates are provided simultaneously and continuously, and respective integrated interposer pyramids can be formed thereon. In this case, each substrate 710 and interposer pyramid 720 can be singulated from other adjacent substrates that are together formed at a wafer level.

Referring to FIG. 5F, after the formation of the substrate 710 and the interposer pyramid 720, the plurality of semiconductor dice may be stacked thereon. Further steps for making the semiconductor package may refer to the above embodiments.

Referring to FIG. 5G, in some embodiments, solder bumps 760 may be mounted on a bottom surface of the substrate 710 to form a semiconductor package 700.

Referring to FIG. 5H, in some embodiments, the method further includes a step of singulating at the central axis C of the semiconductor package 700, thereby, half of the semiconductor package 700-2 can be obtained. It can be understood that, the half 700-2 itself may define a semiconductor package.

FIGS. 3A to 3K, FIGS. 4A to 4G and FIGS. 5A to 5H illustrate three methods for making a semiconductor package such as the semiconductor packages 100, 200 and 300 shown in FIGS. 1A, 1B and 1C, respectively. In the above methods for stacking semiconductor dice, when an upper semiconductor die is attached on a lower semiconductor die and a lower interposer layer, the attachment of the solder bumps of the upper semiconductor die may adopt one or more of the methods illustrated in FIGS. 6A to 6D. FIGS. 6A to 6D take the semiconductor die 840-2 which is formed on both the interposer layer 822-1 and the semiconductor die 840-1 as an example, but it can be understood that, the method illustrated herein may apply to other semiconductor dice.

Referring to FIG. 6A, for the semiconductor die 840-2 attached with the solder bumps 841, flux such as epoxy 860 is applied using a dipping process on the solder bumps 841, the solder bumps 841 are then attached to the semiconductor die 840-1 underneath. Preferably, the solder bumps 841 applied with epoxy 860 may be dummy bumps that only provide mechanical support on the semiconductor die 840-1. Such process is generally referred to as epoxy flux dipping.

Referring to FIG. 6B, at least one dummy pad 870 is formed on a top surface of the lower semiconductor die 840-1, and solder bumps 841 of the semiconductor die 840-2 may be attached on the dummy pads 870. In some embodiments, the dummy pads 870 may be formed by depositing and patterning a metal material such as copper, aluminum on the top surface of the semiconductor die 840-1. The dummy pads 870 may also be formed by sputtering, CVD, PVD, ink printing etc. The dummy pads 870 may have a thickness that is significantly smaller than the height of the dummy bumps 841, which may not affect the horizontal alignment between the semiconductor die 840-2 and an interposer layer which is to be formed at the same level as the semiconductor die 840-2.

Referring to FIG. 6C, pre-dot flux such as pre-dot epoxy 880 may be dispensed on the semiconductor die 840-1. Preferably, pre-dot epoxy 880 is dispensed at or close to the perimeter of solder bumps 841. The pre-dot epoxy 880 has a predetermined height to maintain standoff distance between the lower semiconductor die 840-1 and the upper semiconductor die 840-2 during bonding and prevent interconnect defects.

Referring to FIG. 6D, in some embodiments, the interposer layer 822-1 includes connection structures 823 for connecting power, and each semiconductor die 840-1, 840-2 includes through-silicon-vias 842 for connecting signal input/output. And the upper semiconductor die 840-2 is attached on the interposer layer 822-1 and the semiconductor die 840-1 such that power pins and signal pins of the semiconductor die 840-2 are connected to the connection structures 823 and the through-silicon-vias, respectively.

The discussion herein included numerous illustrative figures that showed various steps in a method of making several semiconductor packages. For illustrative clarity, such figures did not show all aspects of each example assembly. Any of the example assemblies and/or methods provided herein may share any or all characteristics with any or all other assemblies and/or methods provided herein.

Various embodiments have been described herein with reference to the accompanying drawings. It will, however, be evident that various modifications and changes may be made thereto, and additional embodiments may be implemented, without departing from the broader scope of the invention as set forth in the claims that follow. Further, other embodiments will be apparent to those skilled in the art from consideration of the specification and practice of one or more embodiments of the invention disclosed herein. It is intended, therefore, that this application and the examples herein be considered as exemplary only, with a true scope and spirit of the invention being indicated by the following listing of exemplary claims.

1. A method for making a semiconductor package, comprising:
providing a substrate and a plurality of semiconductor dice;
forming an integrated interposer block comprising a first interposer layer, a second interposer layer and a dummy portion, wherein the integrated interposer block defines a central axis, wherein the first interposer layer and the second interposer layer are symmetric with respect to the central axis to form an interposer pyramid, and the dummy portion is at a periphery of the interposer pyramid;
removing the dummy portion from the integrated interposer block to form a pair of step structures on two lateral sides of the interposer pyramid, respectively, wherein each step structure comprises two step surfaces extending from the first interposer layer and the second interposer layer on one side of the interposer pyramid;
attaching the interposer pyramid on the substrate;
attaching a first pair of semiconductor dice on the substrate symmetrically with respect to the central axis and adjacent to two lateral sides of the first interposer layer via solder bumps, respectively;
attaching a second pair of semiconductor dice on the first interposer layer and the first pair of semiconductor dice symmetrically with respect to the central axis via solder bumps; and
forming an encapsulant layer on the substrate to encapsulate the interposer pyramid and the semiconductor dice.

2. The method of claim 1, wherein forming an integrated interposer block comprises:
forming a plurality of layers of connection structures, wherein each layer of connection structures comprises a set of die connection structures and a set of interlayer connection structures extending through the layer;
forming barrier layers on lower layers of connection structures at a position of lower step surfaces, wherein conners of the lower step surfaces are not formed with the barrier layers, and wherein an area on the barrier layers defines the dummy portion of the integrated interposer block;
performing laser drilling at the conners of the lower step surfaces to expose the conners of the lower step surfaces;
removing the barrier layers and the dummy portion from the integrated interposer block; and wherein
upon removing the dummy portion from the integrated interposer block, conductive patterns of the set of die connection structures are exposed from the corresponding step surface at an interposer layer for electrically coupling a corresponding semiconductor die on the step surface.

3. The method of claim 2, wherein removing the dummy portion from the integrated interposer block comprises laser drilling the dummy portion.

4. The method of claim 1, wherein attaching a second pair of semiconductor dice comprises:
applying flux using a dipping process on solder bumps which are attached to the second pair of semiconductor dice;
attaching dummy bumps of the second pair of semiconductor dice on dummy pads of the first pair of semiconductor dice; and/or
dispensing pre-dot flux on the first pair of semiconductor dice.

5. The method of claim 1, wherein each interposer layer comprises connection structures for connecting power, and each semiconductor die comprises through-silicon-vias for connecting signal input/output.

6. The method of claim 1, further comprising: singulating at the central axis.

7. A method for making a semiconductor package, comprising:
providing a plurality of semiconductor dice;
forming an integrated interposer block comprising a substrate, a first interposer layer, a second interposer layer and a dummy portion, wherein the integrated interposer block defines a central axis, wherein the substrate, the first interposer layer and the second interposer layer are symmetric with respect to the central axis to form an interposer pyramid, and the dummy portion is at a periphery of the interposer pyramid and on the substrate;
removing the dummy portion from the integrated interposer block to expose the substrate from the dummy portion and to form a pair of step structures on two lateral sides of the interposer pyramid, respectively, wherein each step structure comprises two step surfaces extending from the first interposer layer and the second interposer layer on one side of the interposer pyramid;
attaching a first pair of semiconductor dice on the substrate symmetrically with respect to the central axis and adjacent to two lateral sides of the first interposer layer via solder bumps, respectively;
attaching a second pair of semiconductor dice on the first interposer layer and the first pair of semiconductor dice symmetrically with respect to the central axis via solder bumps; and
forming an encapsulant layer on the substrate to encapsulate the interposer pyramid and the semiconductor dice.

8. The method of claim 7, wherein forming an integrated interposer block comprises:
forming a plurality of layers of connection structures, wherein each layer of connection structures comprises a set of die connection structures and a set of interlayer connection structures extending through the layer;
forming barrier layers on lower layers of connection structures at a position of lower step surfaces, wherein conners of the lower step surfaces are not formed with the barrier layers, and wherein an area on the barrier layers defines the dummy portion of the integrated interposer block;
performing laser drilling at the conners of the lower step surfaces to expose the conners of the lower step surfaces;
removing the barrier layers and the dummy portion from the integrated interposer block; and wherein
upon removing the dummy portion from the integrated interposer block, conductive patterns of the set of die connection structures are exposed from the corresponding step surface at an interposer layer for electrically coupling a corresponding semiconductor die on the step surface.

9. The method of claim 8, wherein removing the dummy portion from the integrated interposer block comprises laser drilling the dummy portion.

10. The method of claim 7, wherein attaching a second pair of semiconductor dice comprises:
applying flux using a dipping process on solder bumps which are attached to the second pair of semiconductor dice;
attaching dummy bumps of the second pair of semiconductor dice on dummy pads of the first pair of semiconductor dice; and/or
dispensing pre-dot flux on the first pair of semiconductor dice.

11. The method of claim 7, wherein each interposer layer comprises connection structures for connecting power, and each semiconductor die comprises through-silicon-vias for connecting signal input/output.

12. The method of claim 10, further comprising: singulating at the central axis.
